(19) United States
(12) Patent Application Publication
(10) Pub. No.: US 2026/0197544 A1
(43) Pub. Date: Jul. 9, 2026

(54) METHOD FOR CONTROLLING THE TEMPERATURE OF AN IMAGE SENSOR, IMAGE SENSOR DEVICE, MASK INSPECTION APPARATUS

(71) Applicant: Carl Zeiss SMT GmbH, Oberkochen (DE)

(72) Inventors: Julian Zips, Oberkochen (DE); Christoph Traxinger, Oberkochen (DE); Nils Reiche, Oberkochen (DE)

(21) Appl. No.: 19/441,003

(22) Filed: Jan. 6, 2026

(30) Foreign Application Priority Data
Jan. 6, 2025 (DE) 102025100170.7

(51) Int. Cl. H04N 23/52; G03F 7/00; H05K 7/20

(52) U.S. Cl. CPC H04N 23/52; G03F 7/7085; H05K 7/20327; H05K 7/2039

(57) ABSTRACT

Method for controlling the temperature of an image sensor to a setpoint temperature in which a temperature control fluid is conducted along a channel. The channel has a heat exchange section, which is in thermal interaction with the image sensor. The temperature control fluid in the heat exchange section is in a two-phase state. The invention also relates to an image sensor device and to a mask inspection apparatus.

### CROSS-REFERENCE TO RELATED APPLICATION

This application claims benefit under 35 U.S.C. §119 to German Patent Application 10 2025 100 170.7, filed on January 6, 2025, the entire content of which is incorporated herein by reference.

### TECHNICAL FIELD

The invention relates to a method for controlling the temperature of an image sensor, to an image sensor device and to a mask inspection apparatus.

### BACKGROUND

Photomasks are used in microlithographic projection exposure apparatuses with which integrated circuits with particularly small structures are produced. The photomask illuminated by very short-wave extreme ultraviolet radiation (EUV radiation) is imaged onto a lithography object in order to transfer the mask structure to the lithography object.

For a high quality of the imaging generated on the lithography object, it is necessary that the photomask is true to size and not adversely affected by contamination. It is known practice to subject photomasks to an inspection, either prior to operation in a microlithographic projection exposure apparatus or during an interruption in operation. For this purpose, a so-called aerial image of a portion of the photomask is generated, with the photomask not being imaged onto a lithography object but rather onto an image sensor of an EUV camera. The imaging onto the image sensor can be taken as a basis for making an assessment as to whether the photomask is free of defects and contamination.

In order to be able to provide image data of sufficient quality in an EUV environment, an image sensor should be operated at a specified setpoint temperature. The tolerance range for deviations between the actual operating temperature and the setpoint temperature is small. With increasing deviation from the setpoint temperature, the signal-to-noise ratio deteriorates, which is accompanied by reduced quality of the image data.

Unlike in the case of normal temperature control processes, operating an image sensor is not just about minimizing temperature fluctuations. Rather, the requirement goes beyond this in specifying that an absolute value of the temperature should be maintained with high accuracy.

### SUMMARY

The invention is based on the aspect of providing a method for controlling the temperature of an image sensor, an image sensor device and a mask inspection apparatus which allow an image sensor to be operated within a predetermined temperature range. The aspect is achieved by the features of the independent claims. Advantageous embodiments are specified in the dependent claims.

In the case of a method according to the invention for controlling the temperature of an image sensor to a setpoint temperature, a temperature control fluid is conducted along a channel. The channel has a heat exchange section, which is in thermal interaction with the image sensor. The temperature control fluid in the heat exchange section is in a two-phase state.

The invention proposes using a temperature control fluid which is in a two-phase state while heat is being transferred between the temperature control fluid and the image sensor. A temperature control fluid is in a two-phase state as long as it follows an isotherm within a T-s diagram. In the T-s diagram, T denotes the temperature and s the entropy. At a constant temperature T, the temperature control fluid can absorb or emit heat by the entropy increasing or decreasing. In contrast to conventional temperature control processes, it is possible in the invention that the temperature control fluid can flow along the image sensor, with the temperature of the temperature control fluid remaining unchanged despite the heat exchange.

The setpoint temperature for operation of the image sensor may be below the ambient temperature. The temperature control process is then a cooling process. The difference between the setpoint temperature and the ambient temperature may be greater than 5 K, preferably greater than 10 K, more preferably greater than 15 K. The setpoint temperature for the operation of the image sensor may be between -5°C and 5°C, preferably between -2°C and 2°C, more preferably between -0.5°C and 0.5°C. The tolerance range for the difference between the operating temperature of the image sensor and the setpoint temperature may be less than 100 mK, preferably less than 50 mK. In other words, within the tolerance range, the operating temperature may be 50 mK or 100 mK higher or lower than the setpoint temperature.

The temperature control fluid may be circulated. In order to allow constant operation, it is of advantage if the amount of heat exchanged between the image sensor and the temperature control fluid is equalized again at another point in the circuit. The temperature control fluid may therefore be passed through a heat exchanger within the circuit. In the case of a cooling process for the image sensor, in the heat exchanger heat may be given off to the surroundings or a heat sink.

The phase transition which the temperature control fluid undergoes may be a phase transition between liquid and gaseous. The heat exchange section may be enclosed between a restrictor and a pump. The temperature control fluid may enter the heat exchange section from the restrictor. The temperature control fluid may leave the heat exchange section in the direction of the pump.

The pump can be used to increase the pressure of the temperature control fluid. The circuit for the temperature control fluid may comprise a section in which the temperature control fluid is completely in the liquid state of aggregation. The section of the circuit may follow the pump and be upstream of the restrictor. The circuit may be configured in such a way that, after passing through the restrictor, the temperature control fluid has a two-phase state in which part of the temperature control fluid is in a gaseous state and part of the temperature control fluid is in a liquid state.

When the temperature control fluid flows along the image sensor in its two-phase state, the temperature control fluid can absorb heat from the image sensor without the temperature of the temperature control fluid changing. Due to the heat absorbed, part of the temperature control fluid undergoes a transition from liquid to gaseous. The temperature remains unchanged as long as the two-phase state is maintained, i.e., as long as parts of the temperature control fluid are still in a liquid state.

The restrictor and the pump may be coordinated with one another in such a way that the temperature control fluid in the two-phase state has a specified pressure. A constant value of the pressure of the temperature control fluid in the two-phase state results in an associated defined temperature of the temperature control fluid. The restrictor and the pump may be variable, so that, by suitably activating these components, the temperature control fluid in the two-phase state can be set to different temperature values.

In an alternative embodiment, the temperature control fluid in the heat exchange section comprises a liquid phase and a solid phase. A mixture of solid phase and liquid phase forms a temperature control fluid within the meaning of the invention as long as it maintains its fluidity. A temperature control fluid in this sense can be pumped by a pump. The solid phase may make up a small proportion in relation to the total amount of the temperature control fluid. Based on the weight, the proportion of the fixed partial amount may be, for example, less than 20%, preferably less than 10%, more preferably less than 5%. The figure refers to the highest proportion that the fixed phase reaches within the cooling circuit.

A multiplicity of crystallization bodies may be contained in the temperature control fluid. Each crystallization body may form a core for a preferred transition from the liquid state of aggregation to the solid state of aggregation. The crystallization bodies may be formed, for example, by glass bodies, steel bodies and/or polymer bodies. The crystallization bodies may have a greatest diameter which is less than 1 mm, preferably less than 0.5 mm. A cavity formed in the interior, for example, allows the crystallization bodies to be designed in such a way that the density corresponds to the density of the temperature control fluid. In particular, the higher density may deviate from the lower density by less than 10%, preferably by less than 5%. In this way, a very fine distribution of solid constituents of the temperature control fluid can be created and a formation of larger solid agglomerates can be counteracted. With a fine distribution of the solid constituents, the temperature control fluid remains in a state in which it can be pumped well in a circuit by a pump.

In the circuit, the temperature control fluid may be pumped through a heat exchanger. The heat exchanger may be designed to carry out a heat exchange with the surroundings which corresponds to the heat exchange between the image sensor and the temperature control fluid. In this way, the temperature of the temperature control fluid comprising a liquid phase and a solid phase can be kept constant. The temperature control fluid can be in a two-phase state of solid and liquid during the entire circulation.

The temperature control fluid can be selected in such a way that the setpoint temperature of the image sensor corresponds to the temperature of the phase transition between solid and liquid. This can be achieved by mixing different constituents in a suitable proportion in the temperature control fluid. A temperature of the phase transition below 0°C can be achieved, for example, by mixing water with salt, with glycol and/or with ethanol.

The temperature control fluid may flow in the heat exchange section within a channel which is surrounded by a channel wall. The channel wall may form a pipe. The channel may have a cross section of a circular shape or be shaped differently. The cross section of the channel may be constant or vary over the length of the heat exchange section.

In the heat exchange section, the channel wall may be in physical contact with components of the image sensor. In particular, there may be physical contact with such components of the image sensor in which heat is generated during operation of the image sensor. Physical contact between components of the image sensor and the channel wall allows particularly effective heat exchange with the temperature control fluid inside the channel.

Physical contact between the channel wall and components of the image sensor entails the risk that mechanical vibrations can be transferred between the temperature control fluid and the image sensor. This applies in particular to vibrations that arise in the temperature control fluid due to the fact that parts of the temperature control fluid undergo a phase transition when passing through the heat exchange section. For example, gas bubbles forming during a change from liquid to gaseous have a higher volume than the amount of liquid concerned. The formation of gas bubbles may cause vibrations within the temperature control fluid that can be transmitted to components of the image sensor via the channel wall.

To avoid vibrations, it is advantageous if the amount of temperature control fluid that undergoes a phase change when passing the heat exchange section is small in relation to the total amount of liquid that passes the heat exchange section. In particular, the proportion of the temperature control fluid that undergoes a phase transition from liquid to gaseous in the heat exchange section may be less than 10%, preferably less than 5%, more preferably less than 2%.

It is also possible to carry out the method without physical contact between the channel wall and the image sensor. For example, the channel wall may be separated from the components of the image sensor by a gap. The gap may be filled with a gas. A pressure different from atmospheric pressure may be present in the gap. The heat exchange between the components of the image sensor and the temperature control fluid may take place by radiation and/or convention across the gap. The wall of the cooling channel and the components of the image sensor may be interlinked, providing a large surface area over which the heat exchange between the components of the image sensor and the channel wall can take place. For example, cooling ribs of the image sensor may be in engagement with cooling ribs of the channel wall without physical contact between the two.

The temperature of the temperature control fluid may deviate considerably from the setpoint temperature of the image sensor and in particular be considerably lower than the setpoint temperature of the image sensor. For example, the temperature of the temperature control fluid may deviate from the setpoint temperature of the image sensor by at least 40 K, preferably by at least 80 K, more preferably by at least 100 K. Since, because of the gap between the channel wall and the components of the image sensor, direct transmission of mechanical vibrations is not possible, the amount of temperature control fluid that is conducted through the heat exchange section can be set in such a way that a considerable part of the temperature control fluid is subjected to a change in the state of aggregation as a result of heat exchange with the components of the image sensor. For example, at least 40%, preferably at least 60%, more preferably at least 80% may undergo a change of the state of aggregation when flowing through the heat exchange section as a result of heat exchange with the image sensor. The cooling channel may be mechanically decoupled from the image sensor by suitable decoupling elements.

The image sensor may be an EUV image sensor, that is to say an image sensor which is sensitive to EUV radiation. The term EUV radiation is used to refer to electromagnetic radiation in the extreme ultraviolet spectral range with wavelengths of between 5nm and 30nm. In particular, the EUV radiation may have a wavelength of 13.5 nm. The cooling power required to keep the temperature of the image sensor constant during operation may be between 200 W and 400 W. The greatest extent of the sensor area of the image sensor may be between 100 mm and 200 mm.

The invention also relates to an image sensor device with an image sensor and with a temperature control system. The temperature control system comprises a channel and a pump, wherein the channel has a heat exchange section, which is in thermal interaction with the image sensor. The pump is designed to pump the temperature control fluid along the channel, wherein the temperature control fluid in the heat exchange section is in a two-phase state. The invention also relates to a mask inspection apparatus, comprising such an image sensor system, a positioning device for a photomask and a projection lens to image the photomask onto an image sensor of the image sensor system.

The disclosure includes developments of the method with features which are described in conjunction with the image sensor device according to the invention. The disclosure includes developments of the image sensor device with features which are described in conjunction with the method according to the invention.

The disclosure includes further variants which independently have inventive content, even without the temperature control fluid in the heat exchange section being in a two-phase state. These variants can be developed individually or in combination with features disclosed in conjunction with the image sensor device according to the invention or the method according to the invention.

The temperature control fluid may be completely in the liquid phase in the heat exchange section. In a first variant, the temperature control fluid is in a two-phase state in a section of the channel remote from the heat exchange section. In a second variant, the temperature control system comprises a primary circuit and a secondary circuit, which are thermally coupled to one another via a heat exchanger, wherein the heat exchange section is arranged in the primary circuit and wherein the temperature control fluid in a section of the secondary circuit is in a two-phase state. In a third variant, the temperature control fluid comprises water and at least one other constituent, so that the temperature of the phase transition between liquid and solid is below 0°C. The other constituent may comprise, e.g., salt (NaCl), glycol and/or ethanol.

### BRIEF DESCRIPTION OF THE DRAWINGS

The invention is described by way of example below on the basis of advantageous embodiments with reference to the accompanying drawings, in which:

FIG. 1: shows a schematic representation of a mask inspection apparatus according to the invention;

FIG. 2: shows a schematic representation of an image sensor device according to the invention;

FIG. 3: shows a detail from FIG. 2 in an enlarged representation;

FIG. 4: shows the view according to FIG. 2 in an alternative embodiment of the invention;

FIG. 5: shows a detail from FIG. 4 in an enlarged representation;

FIG. 6: shows a detail from FIG. 5 in an enlarged representation;

FIG. 7: shows the view according to FIG. 5 in an alternative embodiment of the invention;

FIGS. 8 and 9: show further variants of image sensor devices.

### DETAILED DESCRIPTION

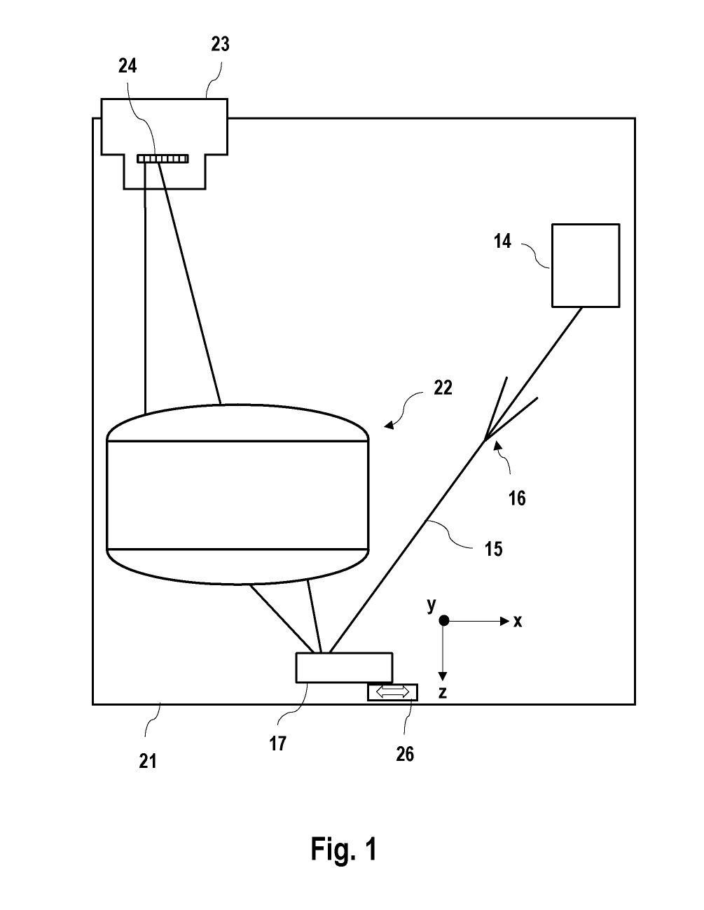

With a mask inspection apparatus shown in FIG. 1, microlithographic photomasks 17 can be examined.

In general, microlithographic photomasks 17 are intended to be used in a microlithographic projection exposure apparatus (not shown). In the microlithographic projection exposure apparatus, the photomask 17 is illuminated with extreme ultraviolet radiation (EUV radiation) at a wavelength of, for example, 13.5 nm in order to image a structure formed on the photomask 17 onto the surface of a lithographic object in the form of a wafer. The wafer is coated with a photoresist which reacts to the EUV radiation. The mask inspection device is used to examine whether the photomask meets the requirements and is free from contamination.

According to FIG. 1, the photomask 17 is arranged in the mask inspection device in such a way that an EUV beam path 15 coming from an EUV radiation source 14 is directed onto the photomask 17 via an illumination system 16. The illumination system 16 is used to shape the EUV radiation to form a beam with which an examination field on the surface of the photomask 17 is illuminated with uniform brightness. The small examination field in relation to the surface area of the photomask 17 may, for example, have dimensions of 0.5 mm x 0.8 mm. The edge lengths of the photomask 17 may be, for example, between 100 mm and 200 mm. A field stop with which the illuminated region is restricted to the examination field on the surface of the photomask 17 is arranged in the illumination system 16. With an X-Y positioning mechanism 26, the photomask can be moved in the X-Y plane in order to bring different examination fields into the region of the EUV beam path.

The EUV beam path 15 reflected at the photomask 17 continues via a projection lens 22 to an EUV camera 23, which is equipped with an image sensor 24. The projection lens is used to image the examination field of the photomask 17 onto the image sensor 24 of the EUV camera 23. The image sensor 24 can be, e.g., a complementary metal oxide semiconductor (CMOS) sensor or a charge coupled device (CCD) sensor. The image sensor 24 can include, e.g., an array of individually addressable sensing elements or pixels that generate images of the examination field of the photomask 17 or other objects. The EUV radiation source 14, the illumination system 15, the photomask 17, the projection lens 22 and the EUV camera 23 are arranged in a vacuum housing 21 in which negative pressure prevails during the operation of the mask inspection device.

In some implementations, the EUV radiation source 14 is a plasma radiation source in which the EUV radiation is emitted at a wavelength of 13.5 nm from a plasma. Tin is a medium that can be used to generate a plasma suitable for emitting such EUV radiation. A laser beam can be made to impinge on a droplet of the medium for the purpose of generating the plasma.

The illumination system 16 and the projection lens 22 may comprise mirrors at which the EUV radiation is reflected. The mirrors may be designed as EUV mirrors, which have particularly high reflectivity for EUV radiation. The optical area of the EUV mirrors may be formed by a highly reflective coating. This may be a multilayer coating, in particular a multilayer coating with alternating layers of molybdenum and silicon. With such a coating, approximately 70% of the incident EUV radiation can be reflected.

The projection lens 22 has a magnification factor of more than 100. In order to be able to capture the entirety of the image produced by the examination field of the photomask 17, the surface area of the image sensor 24 is greater than the surface area of the examination field 20 in accordance with the magnification factor. The image sensor 24 may, for example, have dimensions of the order of magnitude of 100 mm to 200 mm.

The photomask may have an aspect ratio of between 1:1 and 1:3, preferably between 1:1 and 1:2, particularly preferably of 1:1 or 1:2. The photomask may be substantially rectangular. The photomask may preferably have a length and a width of 5 to 7 inches (12.7 cm to 17.8 cm), particularly preferably a length and a width of 6 inches (15.2 cm). As an alternative to this, the photomask may have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The EUV camera 23 comprises a control unit (not shown), which is in communication with the image sensor 24. The control unit actuates the image sensor 24, among other things to determine the times at which the image sensor 24 is exposed in order to capture an image. In each pixel, the amount of incident EUV radiation is then registered and converted into a corresponding number of free charge carriers. Image data can be obtained by reading the number of charge carriers for the individual pixels.

For a high quality of the image data captured, it is necessary that the image sensor 24 is operated at an operating temperature that is well below the ambient temperature. It is not only important to keep the fluctuations in the operating temperature small, but also to keep the absolute value of the operating temperature close to the setpoint temperature. For example, the permissible tolerance may be between +/-50 mK. The EUV camera 23 is therefore equipped with a cooling system, which is designed to remove the heat generated during operation of the image sensor 24 and to keep the image sensor 24 at the setpoint temperature.

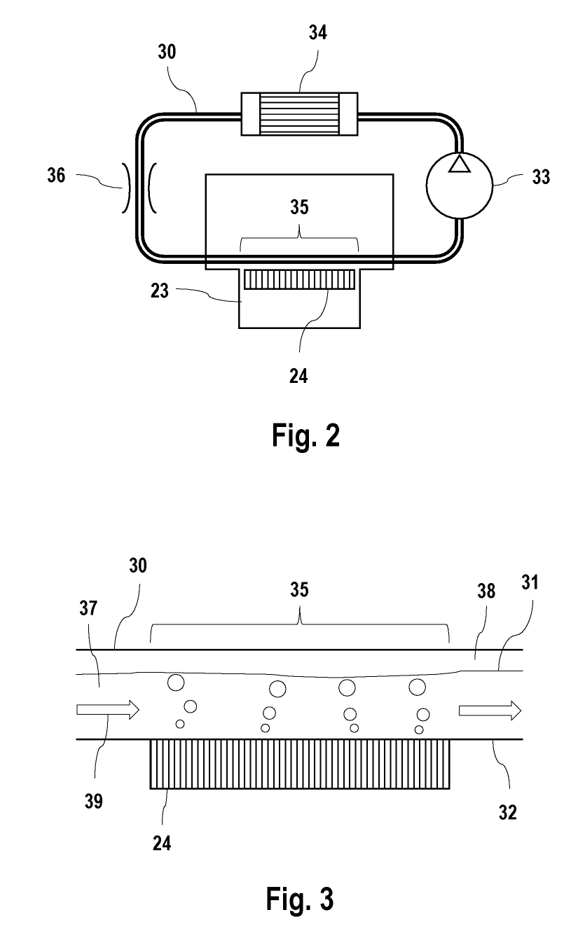

According to FIG. 2, the mask inspection apparatus comprises a cooling system with a cooling channel 30, which extends through the housing of the EUV camera 23. In the cooling channel 30, a temperature control fluid 31 is circulated in a closed manner. The cooling system comprises a pump 33, which drives the flow of the temperature control fluid 31. From the pump 33, the temperature control fluid 31 is pumped in the direction of a heat exchanger 34, in which an amount of heat which corresponds to the amount of heat emitted from the image sensor 24 is given off to the surroundings.

Coming from the heat exchanger 34, the temperature control fluid 31 is conducted through a restrictor 36 before the temperature control fluid 31 enters the interior of the EUV camera 23 through a wall of the EUV camera 23. In the interior of the EUV camera 23, the cooling channel 30 comprises a section in which a channel wall 32 of the cooling channel 30 is in physical contact with the rear side of the image sensor 24. The section of the cooling channel 30 in which the temperature control fluid 31 absorbs heat from the image sensor 24 is referred to as the heat exchange section 35, see FIG. 3.

After leaving the heat exchange section 35, the temperature control fluid 31 exits again from the housing of the EUV image sensor 23. After a short channel section, the temperature control fluid 31 returns to the pump 33.

The pump 33 and the restrictor 36 are coordinated with one another in such a way that the temperature control fluid 31 within the housing of the EUV image sensor 23 is brought to a specified pressure. The pressure is used to set the temperature at which the liquid phase 37 and the gaseous phase 38 go into one another. This temperature is set to match the setpoint temperature at which the image sensor 24 is to be operated.

According to FIG. 3, the temperature control fluid 31 in the heat exchange section 35 is in a two-phase state in which the greater part of the temperature control fluid 31 is in a liquid state of aggregation and the smaller part of the temperature control fluid 31 is in a gaseous state of aggregation.

By absorbing heat from the image sensor 24, a phase transition from liquid to gaseous is triggered, as indicated in FIG. 3 by bubbles within the liquid phase. This phase transition does not cause the temperature to change. Despite the heat absorbed, the temperature of the temperature control fluid 31 at the end of the heat exchange section 35 matched the temperature at the beginning of the heat exchange section 35. Unlike in the case of conventional cooling systems, there is therefore no increase in the temperature of the coolant while the coolant is flowing past the component to be cooled. This opens up the possibility of cooling the image sensor 24 to a specified absolute temperature with high precision.

The flow of the coolant, the direction of flow of which is indicated in FIG. 3 by arrows 39, is designed in such a way that only a small proportion of the temperature control fluid 31 undergoes a phase transition from liquid to gaseous within the heat exchange section 35. The proportion may, for example, be less than 10% of the temperature control fluid 31 that is flowing through the heat exchange section 35. In this way, the mechanical vibrations caused by bubble formation can be reduced. Errors that can be caused by mechanical vibrations in the image data captured are minimized.

With the pump 33, the pressure of the temperature control fluid 31 can be increased in such a way that it is completely in the liquid phase again when it enters the heat exchanger 34. The liquid phase is maintained after passage through the heat exchanger 34, so that defined initial conditions are present at the entrance of the restrictor 36 before the temperature control fluid 31 enters the heat exchange section 35 again.

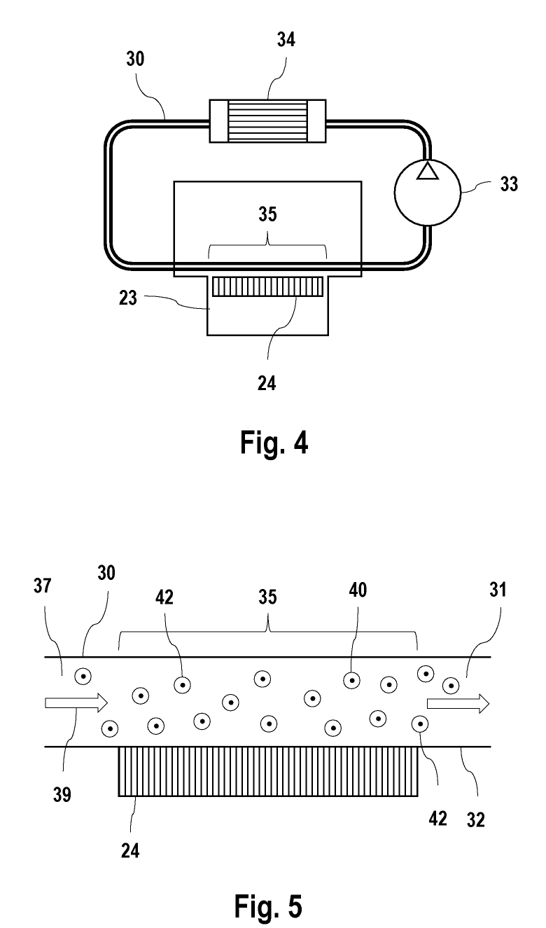

In the case of the alternative embodiment in FIGS. 4-6, the temperature control fluid 31 is circulated without a restrictor mounted in the cooling channel. Just as in the case of the previous exemplary embodiment, the wall 32 of the cooling channel 30 is in physical contact with the rear side of the image sensor 24, so that the temperature control fluid 31 can absorb heat from the image sensor 24. The temperature control fluid 31 is in a two-phase state, in which a liquid phase 37 is mixed with a solid phase 40.

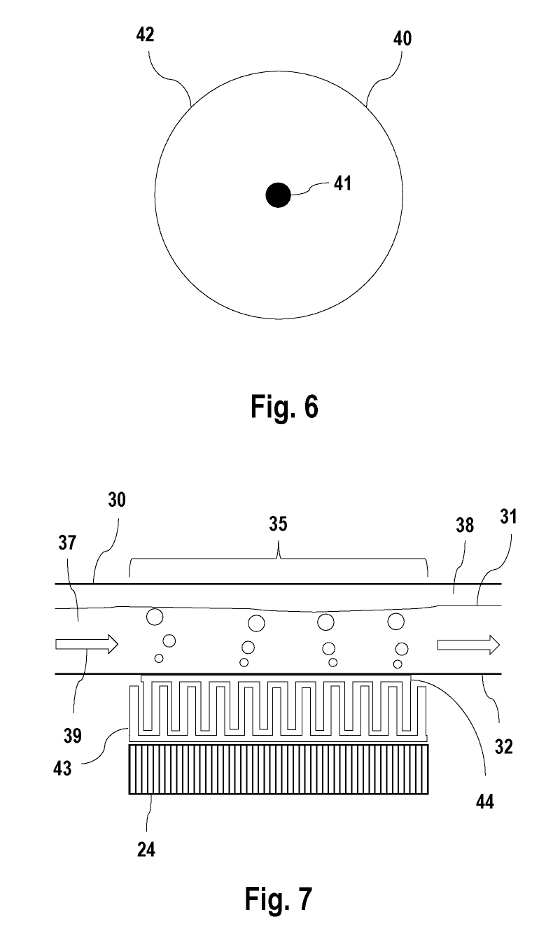

The solid phase 40 takes the form of a multiplicity of small particles 42, which have a substantially uniform distribution within the liquid phase 37. As the enlarged representation of one of the particles 42 in FIG. 6 shows, arranged at the center of each particle 42 is a grain 41 which forms a crystallization point for the phase transition from liquid to solid. If the temperature of the temperature control fluid is cooled from the completely liquid state, the phase transition from liquid to solid first begins at the surfaces of the grains. In this way, the phase transition leads to a large number of small particles 42 in the solid phase instead of individual large agglomerates.

When the temperature control fluid flows along the heat exchange section 35, heat from the image sensor 24 is absorbed, whereby a phase transition from solid to liquid takes place within the temperature control fluid 31. The volume of particles 42 becomes smaller, the volume of the liquid phase 37 increases. In the heat exchanger 34, heat is emitted, so that a phase transition from liquid to solid occurs, whereby the particles 42 become larger again. The amount of heat emitted via the heat exchanger 34 corresponds to the amount of heat absorbed from the image sensor, so that the state of the temperature control fluid 31 remains unchanged when entering the heat exchange section 35 during operation of the cooling system.

Since no larger solids are contained in the temperature control fluid 31, the temperature control fluid 31 can be pumped with the pump 33 similarly to a liquid. In the context of the invention, such a mixture of liquid and solid phase falls under the term temperature control fluid.

The temperature control fluid 31 is prepared in such a way that the temperature at which the liquid phase and the solid phase are in equilibrium corresponds to the operating temperature at which the image sensor 24 is to be operated. If the temperature control fluid is partly water, the temperature of the phase transition between solid and liquid can be set by mixing the water with another substance in a suitable ratio. For example, the water may be mixed with salt (NaCl) or with ethanol to reduce the phase transition temperature to a value below 0°C.

FIG. 7 shows an alternative embodiment in which there is no physical contact between the channel wall 32 of the cooling channel 30 and the image sensor 24. The rear side of the image sensor 24 is equipped with a multiplicity of cooling ribs 43, which extend parallel to one another over the width of the image sensor.

The channel wall 32 of the cooling channel 30 is provided in the heat exchange section 35 with a rib element 44. The rib element 44 is provided with a multiplicity of ribs which extend parallel to the cooling ribs 43 of the image sensor 24. The ribs of the rib element 44 engage in the clearances between the cooling ribs 43 without the ribs touching one another. The heat transfer from the cooling ribs 43 of the image sensor 24 to the ribs of the rib element 44 takes place over the gap lying in between and can be based on heat radiation and/or convection.

For effective heat removal from the image sensor 24, the temperature of the temperature control fluid 31 may be considerably lower than the operating temperature of the image sensor 24. For example, the temperature difference may be between 80 K and 120 K. Since there is no mechanical contact between the cooling ribs 43 of the image sensor 24 and the ribs of the rib element 44, no mechanical vibrations can be transmitted, for which reason the formation of mechanical vibrations in the cooling channel 30 is less critical than in the case of the previously described embodiments. The cooling process may therefore take place in such a way that in the heat exchange section 35 a larger proportion of the temperature control fluid is subjected to a phase transition, for example, a proportion of at least 50%. The phase transition may be a phase transition from liquid to gaseous.

The cooling system is mechanically decoupled in such a way that even outside the heat exchange section 35 vibrations are not transmitted or only to a small extent. For example, in areas in which the cooling channel 30 passes through the housing of the EUV camera 23, suitable decoupling elements between the cooling channel 30 and the housing may be formed.

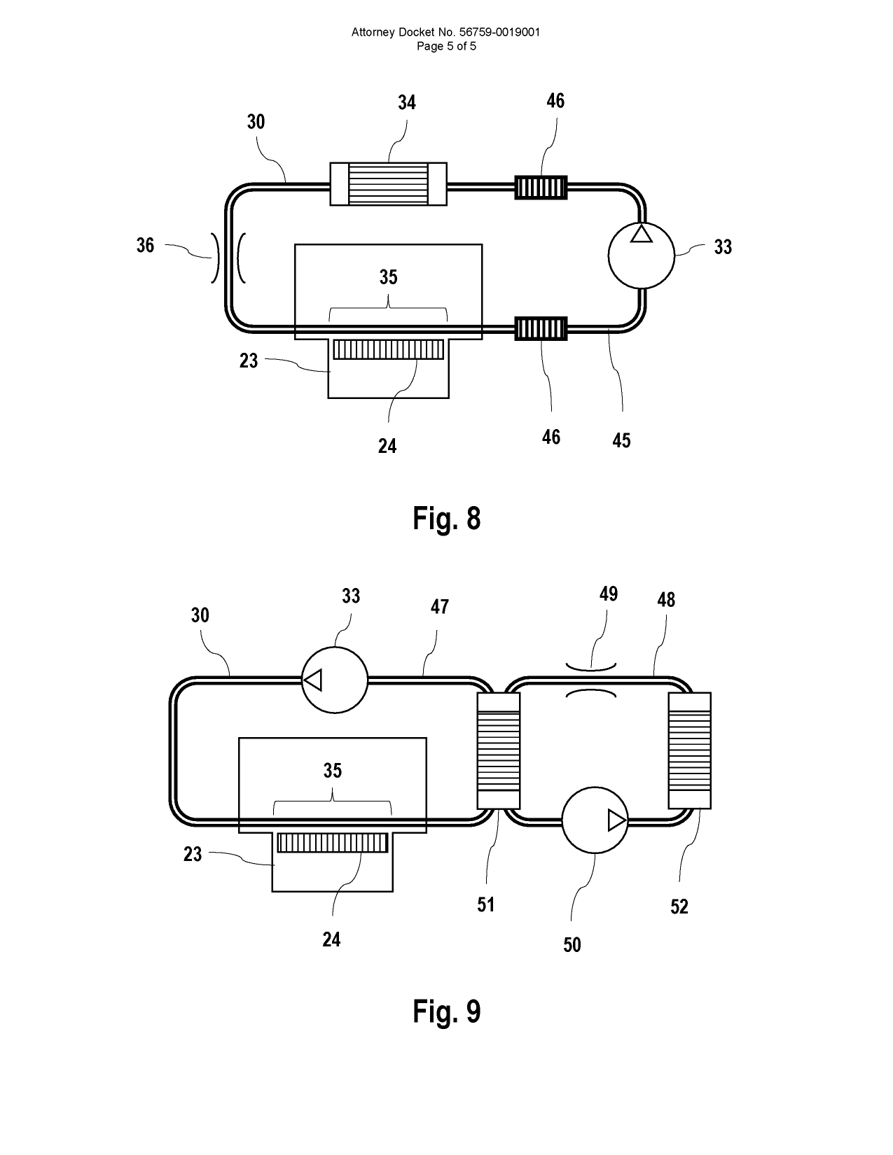

FIG. 8 shows a variant in which the temperature control fluid 31 does not undergo a phase transition in the heat exchange section 35, but in a section 45 of the cooling channel 30 remote from it. By suitable interaction of the pump 33 and the restrictor 36, the operating pressure of the temperature control fluid 31 is set in such a way that the evaporation temperature is slightly above the operating temperature of the image sensor 24. In the heat exchange section 35, the temperature control fluid 31 is completely in the liquid phase. The heat removal from the image sensor 24 takes place by way of liquid cooling. The section 45 of the cooling channel 30 in which the evaporation process takes place is mechanically and acoustically decoupled from the heat exchange section 35 by suitable decoupling elements 46. The risk of transmission of vibrations to the image sensor 24 is reduced.

In the case of the variant shown in FIG. 9, the cooling system comprises a primary circuit 47 and a secondary circuit 48. In the primary circuit 47, the temperature control fluid completely in the liquid phase is circulated by a first pump 33, so that the temperature control fluid in the evaporation section 35 can absorb heat from the image sensor 24. The secondary circuit 48 is coupled to the primary circuit 47 via a first heat exchanger 51, so that heat is transferred from the primary circuit 47 to the secondary circuit 48 and that the temperature of the temperature control fluid in the heat exchange section 35 remains constant during operation of the cooling system. In the secondary circuit 48, by suitable interaction of a second pump 50 with a restrictor 49, a temperature control fluid is set in such a way that it is in a two-phase state in the first heat exchanger 51. A second heat exchanger 52 is used to give off the heat absorbed into the surroundings. Since no phase transition takes place in the primary cooling circuit 47, the risk of vibrations being transmitted to the image sensor 24 is reduced.

A number of embodiments of the invention have been described. Nevertheless, it will be understood that various modifications may be made without departing from the spirit and scope of the invention. For example, the wavelength of the EUV radiation can be different from what is described above. The cooling system can be used to cool image sensors other than those described above. The temperature control fluid can be formed by materials different than those described above. Accordingly, other embodiments are within the scope of the following claims.

What is claimed is:

1. A method for controlling the temperature of an image sensor to a setpoint temperature in which a temperature control fluid is conducted along a channel, wherein the channel has a heat exchange section, which is in thermal interaction with the image sensor, wherein the temperature control fluid in the heat exchange section is in a two-phase state.

2. The method of claim 1, wherein the setpoint temperature is below the ambient temperature.

3. The method of claim 1, wherein the difference between the setpoint temperature and the ambient temperature is greater than 15 K.

4. The method of claim 1, wherein the tolerance range for the difference between the operating temperature of the image sensor and the setpoint temperature is less than 50 mK.

5. The method of claim 1, wherein the temperature control fluid in the heat exchange section comprises a liquid phase and a gaseous phase.

6. The method of claim 5, wherein the temperature control fluid in the heat exchange section undergoes a phase transition from liquid to gaseous.

7. The method of claim 6, wherein the proportion of the temperature control fluid that undergoes a phase transition from liquid to gaseous in the heat exchange section is less than 10%.

8. The method of claim 1, wherein the temperature control fluid in the heat exchange section comprises a liquid phase and a solid phase.

9. The method of claim 8, wherein a multiplicity of crystallization bodies are contained in the temperature control fluid, wherein each crystallization body forms a core for a preferred transition from the liquid state of aggregation to the solid state of aggregation.

10. The method of claim 1, wherein a channel wall of the channel in the heat exchange section is in physical contact with a component of the image sensor.

11. The method of claim 1, wherein a gap is formed between the channel wall of the channel and the image sensor, so that the channel wall has no physical contact with the image sensor.

12. The method of claim 11, wherein the temperature of the temperature control fluid in the heat exchange section deviates from the setpoint temperature of the image sensor by at least 80 K.

13. An image sensor device, comprising an image sensor and a temperature control system, wherein the temperature control system has a channel and a pump, wherein the channel has a heat exchange section, which is in thermal interaction with the image sensor, wherein the pump is designed to pump the temperature control fluid along the channel, wherein the temperature control fluid in the heat exchange section is in a two-phase state.

14. A mask inspection apparatus, comprising an image sensor system, a positioning device for a photomask and a projection lens, in order to image the photomask onto an image sensor of the image sensor system, wherein the image sensor system is formed according to claim 13.

15. The mask inspection apparatus of claim 14, wherein the temperature control fluid in the heat exchange section comprises a liquid phase and a gaseous phase.

16. The mask inspection apparatus of claim 15, wherein the temperature control fluid in the heat exchange section undergoes a phase transition from liquid to gaseous.

17. The mask inspection apparatus of claim 14, wherein the temperature control fluid in the heat exchange section comprises a liquid phase and a solid phase.

18. The mask inspection apparatus of claim 15, wherein a multiplicity of crystallization bodies are contained in the temperature control fluid, wherein each crystallization body forms a core for a preferred transition from the liquid state of aggregation to the solid state of aggregation.

19. The mask inspection apparatus of claim 14, wherein a channel wall of the channel in the heat exchange section is in physical contact with a component of the image sensor.

20. The mask inspection apparatus of claim 14, wherein a gap is formed between the channel wall of the channel and the image sensor, so that the channel wall has no physical contact with the image sensor.
